(19) United States
(12) Patent Application Publication
(10) Pub. No.: US 2021/0058059 A1
(43) Pub. Date: Feb. 25, 2021

(54) PEDESTAL FOR VIBRATION ELEMENT, VIBRATOR, AND OSCILLATOR

(71) Applicant: NIHON DEMPA KOGYO CO., LTD, Tokyo (JP)

(72) Inventors: Takayuki ISHIKAWA, Saitama (JP); Takashi MATSUMOTO, Saitama (JP); Kazumasa IKOMA, Saitama (JP); Takafumi SAITO, Saitama (JP)

(21) Appl. No.: 17/090,351

(22) Filed: Nov. 5, 2020

Related U.S. Application Data
(63) Continuation of application No. PCT/JP2019/019196, filed on May 14, 2019.

(30) Foreign Application Priority Data
May 28, 2018 (JP) 2018-101612
Jun. 15, 2018 (JP) 2018-114257
Jul. 25, 2018 (JP) 2018-139640

(51) Int. Cl. H03H 9/05; H03H 9/19; H03B 1/00

(52) U.S. Cl. CPC H03H 9/05; H03B 1/00; H03H 9/19

(57) ABSTRACT

A pedestal for a vibration element, a vibrator, and an oscillator are provided, which can improve vibration resistance by suppressing the influence of vibration from the outside and can improve phase noise characteristics. The pedestal includes connection parts 14 connected to a substrate of a package 3 along the long side of a main body, gap parts 10c and 10d formed inside the connection parts 14 along the long side, a mounting part 11 for a crystal piece 2 sandwiched between the gap parts 10c and 10d, and arc-shaped curved arm parts 13 connecting the mounting part 11 and the connection parts 14 at the four corners of the main body. The vibrator and the oscillator each include the pedestal.

This application is a continuation of International Application PCT/JP2019/019196 filed May 14, 2019 and published in Japanese and designated the U.S., which claims priority to Japanese Patent Application No. 2018-101612 filed May 28, 2018, Japanese Patent Application No. 2018-114257 filed Jun. 15, 2018, and Japanese Patent Application No. 2018-139640 filed Jul. 25, 2018. The contents of these applications are incorporated herein by reference.

### BACKGROUND OF THE INVENTION

### 1. Field of the Invention

The present invention relates to a pedestal on which a vibration element is mounted, and especially, relates to a pedestal for a vibration element, a vibrator, and an oscillator, which can improve resistance to vibration from the outside to improve phase noise characteristics.

### 2. DESCRIPTION OF THE RELATED ART

### Related Art

There has been known a conventional crystal vibrator having a configuration of using a pedestal (crystal pedestal) mainly made of quartz crystal as a configuration of suppressing the influence on a crystal piece from a package and the outside of the package.

Moreover, there is a crystal oscillator that has the H structure in which recessed portions are formed on the front and back of a package. Herein, a crystal piece and a crystal pedestal are mounted on the front side of the package, and an integrated circuit (IC) for an oscillation circuit is mounted on the back surface.

There is also a temperature-compensated crystal oscillator (TCXO) in which a temperature compensation circuit is provided on the front surface or back surface of a package.

### Related Art

Related conventional arts include Japanese Patent No. 3017750 “crystal vibrator” (Patent Literature 1), Japanese Patent No. 4715252 “piezoelectric vibrator” (Patent Literature 2), and Japanese Patent Laid-Open Publication No. 2013-098678 “crystal vibrator” (Patent Literature 3).

Patent Literature 1 discloses a crystal vibrator in which a recessed portion is formed at a position where a vibrating crystal piece is mounted on a holding crystal plate and the vibrating crystal piece is surely excited in a gap formed by the recessed portion so as not to generate stress due to heat in a longitudinal direction of an excitation crystal piece.

Patent Literature 2 discloses a piezoelectric vibrator that includes a spring part having a gap to reduce the influence of thermal expansion on a substrate.

Patent Literature 3 discloses a crystal vibrator that prevents deformation of a crystal piece due to temperature change to obtain good frequency temperature characteristics.

### RELATED ART LITERATURE

### Patent Literatures

[Patent Literature 1] Japanese Patent No. 3017750

[Patent Literature 2] Japanese Patent No. 4715252

[Patent Literature 3] Japanese Patent Laid-Open Publication No. 2013-098678

However, a crystal pedestal in the conventional crystal vibrator or crystal oscillator has a problem that vibration from the outside affects a crystal piece and phase noise characteristics deteriorate due to the vibration.

Moreover, Patent Literatures 1 to 3 do not disclose a configuration that vibration resistance to vibration from the outside is improved by thickening an electrode section that contacts a substrate of ceramic etc. and thinning a mounting part on which a crystal piece is mounted to float the crystal piece from the substrate and further thinning a portion connecting the electrode section and the mounting part.

### SUMMARY OF THE INVENTION

The present invention has been made in view of the above circumstances, and an object of the present invention is to provide a pedestal for a vibration element, a vibrator, and an oscillator, which can improve vibration resistance by suppressing the influence of vibration from the outside and can improve phase noise characteristics.

According to an embodiment of the present invention for solving the problems of the above conventional example, a pedestal for a vibration element on which the vibration element is mounted and that is provided on a substrate of a package. The pedestal includes: two connection parts that are formed along a long side of a main body of the pedestal, the two connection parts contacting the substrate; two gap parts that are formed along the long side inside the main body from the connection parts; a mounting part that is sandwiched between the two gap parts, the vibration element being mounted on the mounting part; and arm parts that are formed on four corners of the main body, the arm parts connecting the mounting part and the connection parts. Therefore, even if vibration from the outside is transmitted to the connection parts, the vibration can be absorbed by the arm parts to be prevented from being transmitted to the mounting part and phase noise characteristics can be improved.

In the pedestal, the connection parts and the mounting part may have a same thickness, and a thickness of each of the arm parts may be thinner than that of the connection parts and the mounting part. Therefore, even if vibration from the outside is transmitted to the connection parts, the vibration can be absorbed by the arm parts to be prevented from being transmitted to the mounting part and phase noise characteristics can be improved, and a production cost can be reduced by having two types of thickness.

In the pedestal, the connection parts, the mounting part, and the arm parts may have a same thickness. Therefore, even if vibration from the outside is transmitted to the connection parts, the vibration can be absorbed by the arm parts to be prevented from being transmitted to the mounting part and phase noise characteristics can be improved, and a production cost can be further reduced by having one type of thickness.

In the pedestal, a length of each of the gap parts along the long side of the main body may be equal to or greater than half of a length of a long side of the package. Therefore, even if vibration from the outside is transmitted to the connection parts, the vibration can be absorbed by the arm parts to be prevented from being transmitted to the mounting part and phase noise characteristics can be improved.

In the pedestal, each of the gap parts may include a portion formed along the long side of the main body and portions formed along a short side of the main body, and a total length of the portion formed along the long side and the portions formed along the short side may be longer than a length of the long side of the main body.

In the pedestal, the arm parts may have a shape curved in an arc shape.

In the pedestal, the connection parts may protrude toward the substrate.

In the pedestal, each of the arm parts may have a thinner thickness than the mounting part and have a narrower width than each of the connection parts.

In the pedestal, the mounting part may include a cutout portion in which a short side thereof is cut out toward a center side, and the arm part may extend to the short side of the cut-out mounting part and be connected to the mounting part.

A vibrator includes a pedestal on which a vibration element is mounted and that is provided on a substrate of a package, moreover the pedestal comprises: two connection parts that are formed along a long side of a main body of the pedestal, the two connection parts contacting the substrate; two gap parts that are formed along the long side inside the main body from the connection parts; a mounting part that is sandwiched between the two gap parts, the vibration element being mounted on the mounting part; and arm parts that are formed on four corners of the main body, the arm parts connecting the mounting part and the connection parts.

In the vibrator, the pedestal may be provided on the substrate on a bottom surface of a surface recessed portion of the package.

In the vibrator, the connection parts and the mounting part of the pedestal may have a same thickness, and a thickness of each of the arm parts of the pedestal may be thinner than that of the connection parts and the mounting part, and the connection parts of the pedestal may be provided to contact a step portion formed inside a surface recessed portion of the package.

In the vibrator, the connection parts, the mounting part, and the arm parts of the pedestal may have a same thickness, and the connection parts of the pedestal may be provided to contact a step portion formed inside a surface recessed portion of the package.

In the vibrator, the connection parts and the mounting part of the pedestal may have a same thickness, and a thickness of each of the arm parts of the pedestal may be thinner than that of the connection parts and the mounting part, and the connection parts may be provided to be raised by bumps so that a back surface of the mounting part of the pedestal does not contact the substrate on a bottom surface of a surface recessed portion of the package.

An oscillator includes: a pedestal on which a vibration element is mounted and that is provided on a substrate of a package, and an oscillation circuit being provided in the package, moreover the pedestal comprises: two connection parts that are formed along a long side of a main body of the pedestal, the two connection parts contacting the substrate; two gap parts that are formed along the long side inside the main body from the connection parts; a mounting part that is sandwiched between the two gap parts, the vibration element being mounted on the mounting part; and arm parts that are formed on four corners of the main body, the arm parts connecting the mounting part and the connection parts.

In the oscillator, the pedestal may be provided on the substrate on a bottom surface of a surface recessed portion of the package, and the oscillation circuit may be mounted on a back recessed portion of the package.

In the oscillator, the connection parts and the mounting part of the pedestal may have a same thickness, and a thickness of each of the arm parts of the pedestal may be thinner than that of the connection parts and the mounting part, and the connection parts of the pedestal may be provided to contact a step portion formed inside a surface recessed portion of the package, and the oscillation circuit may be mounted on a back recessed portion of the package.

In the oscillator, the connection parts, the mounting part, and the arm parts of the pedestal may have a same thickness, and the connection parts of the pedestal may be provided to contact a step portion formed inside a surface recessed portion of the package, and the oscillation circuit may be mounted on a back recessed portion of the package.

In the oscillator, the connection parts and the mounting part of the pedestal may have a same thickness, and a thickness of each of the arm parts of the pedestal may be thinner than that of the connection parts and the mounting part, and the connection parts may be provided to be raised by bumps so that a back surface of the mounting part of the pedestal does not contact the substrate on a bottom surface of a surface recessed portion of the package, and the oscillation circuit may be mounted on a back recessed portion of the package.

### BRIEF DESCRIPTION OF THE DRAWINGS

FIG. 1 is a schematic view illustrating the present oscillator;

FIG. 2 is an explanatory view illustrating a surface of a first pedestal;

FIG. 3 is an explanatory view illustrating a long side surface of the first pedestal;

FIG. 4 is an explanatory view illustrating a short side surface of the first pedestal;

FIG. 5 is an explanatory view illustrating a back surface of the first pedestal;

FIG. 6 is a perspective view illustrating the surface of the first pedestal;

FIG. 7 is a perspective view illustrating the back surface of the first pedestal;

FIG. 8 is an explanatory view illustrating the surface of the first pedestal according to an application example;

FIG. 9 is an explanatory view illustrating a surface of a second pedestal;

FIG. 10 is an explanatory view illustrating a long side surface of the second pedestal;

FIG. 11 is an explanatory view illustrating a short side surface of the second pedestal;

FIG. 12 is an explanatory view illustrating a back surface of the second pedestal;

FIG. 13 is a perspective view illustrating the surface of the second pedestal;

FIG. 14 is a perspective view illustrating the back surface of the second pedestal;

FIG. 15 is an explanatory view illustrating a cross section of the second pedestal and a package;

FIG. 16 is an explanatory view illustrating a cross section of the second pedestal and another package;

FIG. 17 is an explanatory view illustrating a long side surface of a third pedestal;

FIG. 18 is an explanatory view illustrating a short side surface of the third pedestal;

FIG. 19 is a perspective view illustrating a surface of the third pedestal;

FIG. 20 is an explanatory view illustrating a surface of a fourth pedestal;

FIG. 21 is an explanatory view illustrating a long side surface of the fourth pedestal;

FIG. 22 is an explanatory view illustrating a short side surface of the fourth pedestal;

FIG. 23 is an explanatory view illustrating a back surface of the fourth pedestal;

FIG. 24 is a perspective view illustrating the surface of the fourth pedestal;

FIG. 25 is a perspective view illustrating the back surface of the fourth pedestal; and

FIG. 26 is an enlarged view illustrating the surface of the fourth pedestal.

### DESCRIPTION OF REFERENCE NUMERALS

1, 1a, 1b, 1c, 1d . . . pedestal, 2 . . . crystal piece, 3, 3a, 3b . . . package, 4 . . . oscillation circuit (IC), 5 . . . seam ring, 6 . . . lid, 10a1, 10b1, 10b1-1, 10a2, 10b2, 10a3, 10b3 . . . electrode pattern, 10c, 10d . . . gap part, 11 . . . mounting part, 13 . . . arm part, 14, 14b, 14c, 14d . . . connection part

### DESCRIPTION OF PREFERRED EMBODIMENT

Exemplary embodiments of the present invention will be explained with reference to the accompanying drawings.

[Outline of Embodiment]

A first pedestal for a vibration element (first pedestal) according to an embodiment of the present invention includes connection parts to be connected to a substrate of a package along a long side, gap parts formed along the long side inside the connection parts, a mounting part for the vibration element sandwiched between the gap parts, and arm parts connecting the mounting part and the connection parts. Even if vibration from the outside is transmitted to the connection parts, the first pedestal can improve phase noise characteristics by absorbing the vibration by the arm parts to be able to prevent transmission to the mounting part.

Moreover, a second pedestal for the vibration element (second pedestal) according to the embodiment of the present invention includes connection parts to be connected to the substrate of the package along the long side, gap parts formed along the long side inside the connection parts, a mounting part for the vibration element sandwiched between the gap parts, and arm parts connecting the mounting part and the connection parts, in which the connection parts and the mounting part have the same thickness and the thickness of each of the arm parts is thinner than that of the connection parts and the mounting part. Even if vibration from the outside is transmitted to the connection parts, the second pedestal can improve phase noise characteristics and can reduce a production cost by absorbing the vibration by the arm parts to be able to prevent transmission to the mounting part.

Moreover, a third pedestal for the vibration element (third pedestal) according to the embodiment of the present invention includes connection parts to be connected to the substrate of the package along the long side, gap parts formed along the long side inside the connection parts, a mounting part for the vibration element sandwiched between the gap parts, and arm parts connecting the mounting part and the connection parts, in which the connection parts, the mounting part, and the arm parts have the same thickness. Even if vibration from the outside is transmitted to the connection parts, the third pedestal can improve phase noise characteristics and can reduce a production cost by absorbing the vibration by the arm parts to be able to prevent transmission to the mounting part.

Moreover, a fourth pedestal for the vibration element (fourth pedestal) according to the embodiment of the present invention includes connection parts to be connected to the substrate of the package along the long side, gap parts formed along the long side inside the connection parts, a mounting part for the vibration element sandwiched between the gap parts, and arm parts connecting the mounting part and the connection parts, in which the length of each of the gap parts along the long side of the main body is equal to or greater than half of the length of the long side of the package. Even if vibration from the outside is transmitted to the connection parts, the fourth pedestal can improve phase noise characteristics by absorbing the vibration by the arm parts to be able to prevent transmission to the mounting part.

Especially, in the present pedestal, each of the gap parts includes a portion formed along the long side of the main body and portions formed along the short side of the main body, and a total length of the portion formed along the long side and the portions formed along the short side is longer than the length of the long side of the main body.

A vibrator (the present vibrator) according to the embodiment of the present invention is one in which the vibration element is mounted on each of the first to fourth pedestals and the pedestal is provided on the package having a recessed portion.

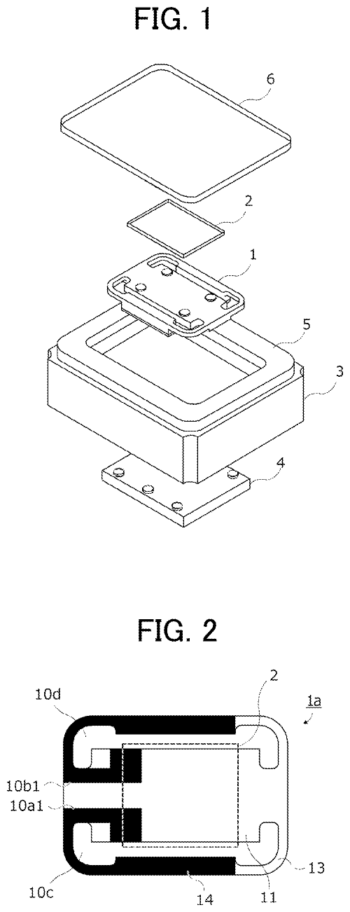

Moreover, an oscillator (the present oscillator) according to the embodiment of the present invention is one in which an oscillation circuit is mounted on the back recessed portion of the package of the present vibrator.

[The Present Oscillator: FIG. 1]

The present oscillator will be explained with reference to FIG. 1. FIG. 1 is a schematic view illustrating the present oscillator.

As illustrated in FIG. 1, the present oscillator basically includes a crystal piece 2, a pedestal 1 on which the crystal piece 2 is mounted, a package 3 in which the pedestal 1 is housed in a surface recessed portion thereof to be mounted on a bottom surface (substrate) of the recessed portion, an oscillation circuit (IC) 4 that is mounted on a back recessed portion of the package 3, a seam ring 5 that is formed around the surface of the package 3, and a lid 6 that acts as a cover.

For example, an AT cut in which thickness shear vibration is excited is used for the crystal piece 2.

[Each Part of the Present Oscillator]

Each part of the present oscillator will be specifically explained.

For example, the pedestal 1 is formed of insulating material such as resin such as heat-resistant plastic, glass, and metal whose surface is coated with an insulating film.

Moreover, the pedestal 1 may be formed of the same crystal (the same AT cut and Z plate as the crystal piece 2) as the crystal piece 2. In that case, thermal expansion coefficients of the pedestal 1 and the crystal piece 2 are substantially equal to each other, and stress due to temperature change does not occur. The details of the pedestal 1 will be described later.

The crystal piece 2 is mounted on the pedestal 1 by being fixed with conductive adhesive.

Excitation electrodes are formed on the front and back surfaces of the crystal piece 2, and are connected to the electrode patterns of the pedestal 1 with the conductive adhesive.

Moreover, a vibration element to be mounted on the pedestal 1 employs a crystal resonator made of the AT-cut crystal piece 2, but for example, may employ a surface acoustic wave (SAW) resonator, or an oscillation element (vibration element) for a vibrator such as another piezoelectric vibrator and a micro electro mechanical system (MEMS) vibrator.

The package 3 is formed of ceramic or the like and has an H-shaped cross section in which recessed portions are formed on both sides of the front and back surfaces. The pedestal 1 and the crystal piece 2 are stored in the surface recessed portion, the pedestal 1 is mounted on the bottom surface (substrate) of the recessed portion, and the oscillation circuit 4 is housed in and mounted on the back recessed portion.

The pedestal 1 and the oscillation circuit 4 mounted on the package 3 are fixed by soldering or the like.

The oscillation circuit (IC) 4 is stored in the back recessed portion of the package 3 to be mounted on the bottom surface (substrate) of the recessed portion. Moreover, a temperature compensation circuit other than the IC 4 may be provided on the surface substrate or the back substrate of the package 3. When the temperature compensation circuit is included, the oscillator acts as a temperature-compensated crystal oscillator (TCXO).

The seam ring 5 is formed of silver solder or the like around the surface of the package 3 in order to perform seam sealing.

The lid 6 acts as a cover, and is one obtained by plating Kovar with nickel and is formed to adhere to the seam ring 5.

[First Pedestal: FIGS. 2 to 7]

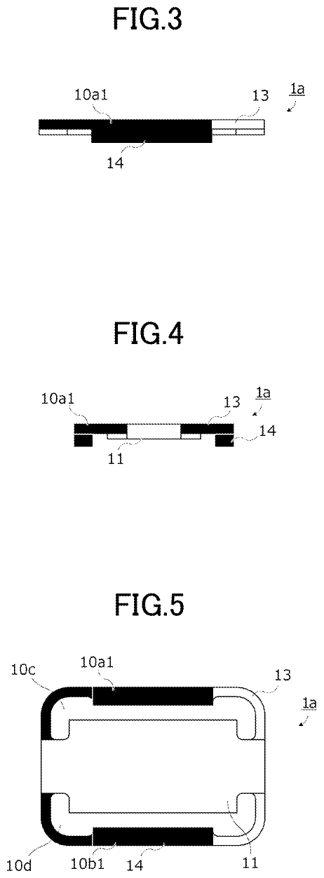

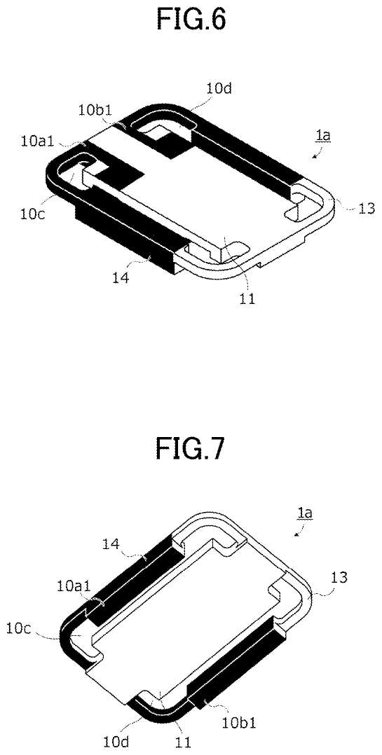

Next, a first pedestal 1a in the present oscillator will be explained with reference to FIGS. 2 to 7. FIG. 2 is an explanatory view illustrating a surface of the first pedestal. FIG. 3 is an explanatory view illustrating a long side surface of the first pedestal. FIG. 4 is an explanatory view illustrating a short side surface of the first pedestal. FIG. 5 is an explanatory view illustrating a back surface of the first pedestal. FIG. 6 is a perspective view illustrating the surface of the first pedestal. FIG. 7 is a perspective view illustrating the back surface of the first pedestal.

As illustrated in FIG. 2, the first pedestal 1a includes gap parts 10c and 10d that are formed inside along the two long sides of a main body, a central mounting part 11 that is sandwiched between the gap parts 10c and 10d and on which the crystal piece 2 is mounted, arm parts 13 that are curved in an arc shape at the four corners of the main body, and connection parts 14 that are provided in parallel with the long side of the mounting part 11 to be connected to electrodes formed on the substrate (bottom surface) of the package 3.

The arm parts 13 are curved to have an arm-like structure.

The mounting part 11 is formed from one short side to the other short side. The short side of the mounting part 11 forms a part of the short side of the main body.

In other words, the first pedestal 1a has a configuration that the arm parts 13 and the connection parts 14 are formed to surround the rectangular mounting part 11 and the mounting part 11 and the connection parts 14 are connected by the arm parts 13.

The two U-shaped gap parts 10c and 10d are formed along the long sides of the mounting part 11. The gap parts 10c and 10d penetrate through the front and back of the first pedestal 1a.

Herein, the width of the short side (the vertical length of FIG. 2) of the mounting part 11 is narrower than the width of the center. Thereby, the gap parts 10c and 10d are opened toward the up and down to have a U shape.

With this configuration, the first pedestal has larger flexibility (elasticity).

The connection parts 14 protrude to the lower side (substrate side) of the package 3 compared to the other component parts. In other words, the contact with the substrate of the package 3 is performed by only the connection parts 14.

Moreover, as illustrated in FIGS. 2 and 5 to 7, the width of the connection parts 14 is wider than that of the arm parts 13. Thus, a joining area with the substrate of the package 3 can be increased, and the arm parts 13 are flexed to have flexibility (elasticity) by making the arm parts 13 a narrow width.

As illustrated in FIG. 2, electrode patterns 10a1 and 10b1 are formed on the surface of the first pedestal 1a. The electrode patterns 10a1 and 10b1 are formed of thin films of metal such as gold.

Specifically, square patterns to which conductive adhesive is applied are in portions overlapping with the crystal piece 2, and patterns are formed from the portions to the right-side ends of the connection parts 14 via the arm parts 13 close to the portions.

Furthermore, as illustrated in FIGS. 3, 4, 6, and 7, the electrode patterns 10a1 and 10b1 are formed on the side surfaces of the arm parts 13 and the side surfaces of the connection parts 14.

Moreover, as illustrated in FIGS. 5 and 7, in the back surface of the present pedestal 1, the electrode patterns 10a1 and 10b1 are formed on the back sides of the arm parts 13 and the connection parts 14.

Moreover, the conductive adhesive is formed near the four corners of the crystal piece 2 to fix the crystal piece 2.

Assuming that the thickness of the mounting part 11 is “a” and the thickness of the arm parts 13 is “b”, the relationship is “a>b”. Moreover, the thickness “c” of the connection parts 14 has the relationship “c>a>b”.

In other words, the thickness “c” of the connection parts 14 that contact the substrate of the package 3 is the thickest, and the thickness “b” of the arm parts 13 is the thinnest.

This is a structure in which only the bottom surfaces of the connection parts 14 are connected to the substrate of the package 3 by most thickening the thickness of the connection parts 14 and thus the arm parts 13 and the mounting part 11 can be floated from the substrate.

As a result, even if vibration is added to the connection parts 14 from the outside, the vibration can be absorbed and relieved by the arm parts 13. For that reason, the influence of the vibration generated on the substrate does not affect the crystal piece 2 mounted on the mounting part 11.

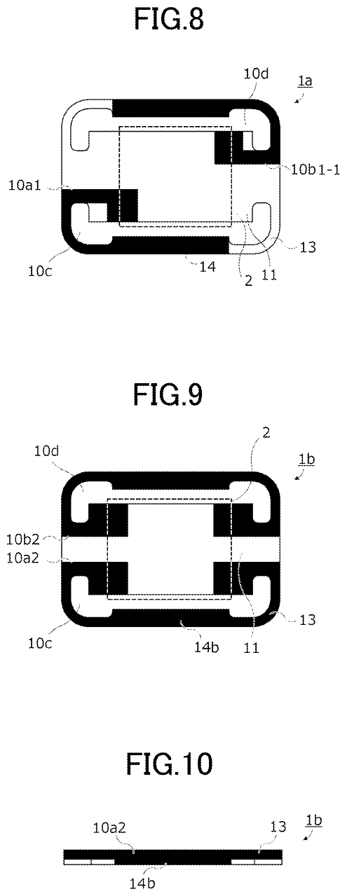

Moreover, by most thinning the thickness of the arm parts 13, the arm parts 13 have flexibility with respect to stress and thus can easily absorb the influence of the vibration. Furthermore, by making the thickness of the mounting part 11 thicker than that of the arm parts 13 to increase the rigidity of the mounting part, it is possible to prevent the mounting part 11 itself from being deformed due to stress from the plurality of arm parts 13. As a result, the occurrence of stress between the mounting part 11 and the crystal piece 2 can be suppressed, and thus vibration resistance and impact resistance can be improved.

[Application Example of First Pedestal: FIG. 8]

An application example of the first pedestal will be explained with reference to FIG. 8. FIG. 8 is an explanatory view illustrating the surface of the first pedestal according to an application example.

As illustrated in FIG. 8, in the first pedestal 1a according to the application example, electrode patterns 10a1 and 10b1-1 are diagonally shaped and are formed with respect to the center point of the mounting part 11 in a point-symmetrical manner.

Also in this case, the crystal piece 2 is fixed to the first pedestal 1a by conductive adhesive near the four corners of the crystal piece.

The application example shows the variation of the electrode patterns.

The first pedestal 1a has the configuration that each surface of the mounting part 11, the arm parts 13, and the connection parts 14 is a plane (flush) and the mounting part 11 and the connection parts 14 protrude from the back surface. However, another application example of the first pedestal 1a may have a configuration that each back surface of the mounting part 11 and the arm parts 13 is flush and the mounting part 11 protrudes from the surface.

[Effects of First Pedestal]

According to the first pedestal 1a and the pedestal 1a of the application example, electrode patterns on the back sides of the connection parts 14 are fixed to electrode patterns formed on the substrate of the package 3 by soldering, and the mounting part 11 surrounded by the gap parts 10c and 10d is connected to the arm parts 13. Therefore, even if vibration from the outside is transmitted to the connection parts 14, the vibration can be absorbed by the arm parts 13 to be prevented from being transmitted to the mounting part 11 and thus phase noise characteristics can be improved.

[Second Pedestal: FIGS. 9 to 14]

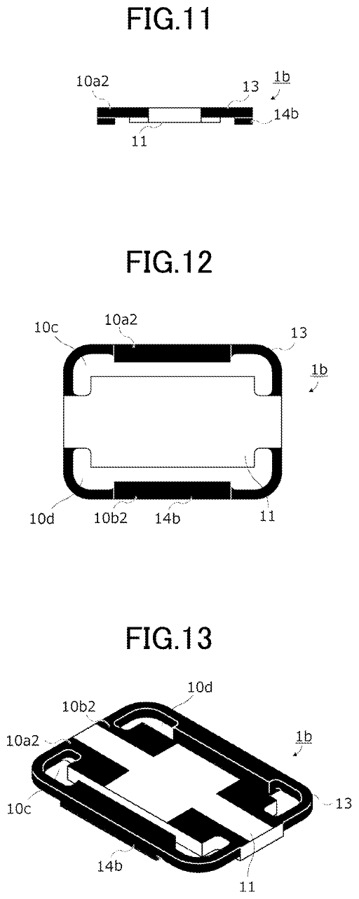

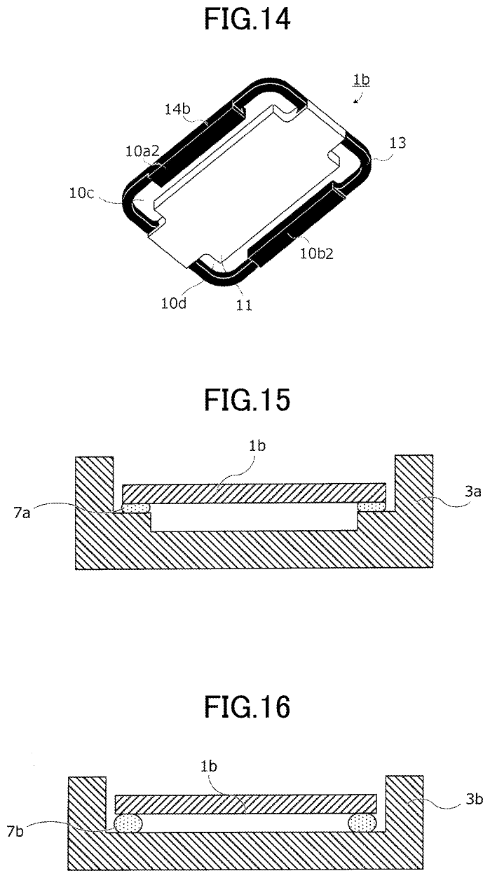

Next, a second pedestal 1b will be explained with reference to FIGS. 9 to 14. FIG. 9 is an explanatory view illustrating a surface of the second pedestal. FIG. 10 is an explanatory view illustrating a long side surface of the second pedestal. FIG. 11 is an explanatory view illustrating a short side surface of the second pedestal. FIG. 12 is an explanatory view illustrating a back surface of the second pedestal. FIG. 13 is a perspective view illustrating the surface of the second pedestal. FIG. 14 is a perspective view illustrating the back surface of the second pedestal.

As illustrated in FIG. 9, the second pedestal 1b includes the gap parts 10c and 10d that are formed inside along the two long sides of a main body, the central mounting part 11 that is sandwiched between by the gap parts 10c and 10d and on which the crystal piece 2 is mounted, the arm parts 13 that are curved in an arc shape at the four corners of the main body, and connection parts 14b that are provided on the long sides of the main body to be connected to electrodes formed on the substrate (bottom surface) of the package 3.

The arm parts 13 are curved to have an arm-like structure and connect the connection parts 14b and the mounting part 11 to each other.

In other words, the second pedestal 1b has a configuration that the arm parts 13 and the connection parts 14b are formed to surround the rectangular mounting part 11 and the mounting part 11 and the connection parts 14b are connected by the arm parts 13.

Moreover, the two U-shaped gap parts 10c and 10d are formed along the long sides of the mounting part 11. The gap parts 10c and 10d penetrate through the front and back of the second pedestal 1b.

Herein, the width of the short side (the vertical length in FIG. 9) of the mounting part 11 is narrower than that of the center. Thereby, the gap parts 10c and 10d are opened toward the up and down to have a U shape. With this configuration, the second pedestal has larger flexibility (elasticity).

Moreover, the mounting part 11 and the connection parts 14b are formed with the same thickness, and protrude toward the lower side (the substrate side) of the package 3 compared to the arm parts 13. Therefore, a method in which only the connection parts 14b contact the substrate of the package 3 uses a mounting method to be described later.

In the mounting part 11 illustrated in FIG. 9, a cutout portion in which the central portion of the short side of the main body is cut out inward may be provided and the arm part 13 may be extended to the short side of the cut-out mounting part 11 and be connected to the mounting part. In this case, the extended arm part 13 has the same thin thickness as that of the other arm parts 13.

As illustrated in FIGS. 9 and 12 to 14, the connection parts 14b have a wider width than that of the arm parts 13. Thus, a joining area with the substrate of the package 3 can be increased, and the arm parts 13 are flexed to have flexibility (elasticity) by making the arm parts 13 a narrow width.

As illustrated in FIG. 9, electrode patterns 10a2 and 10b2 are formed on the surface of the second pedestal 1b. The electrode patterns 10a2 and 10b2 are formed of thin films of metal such as gold.

Specifically, square patterns to which conductive adhesive is applied are in portions overlapping with the crystal piece 2, and patterns are drawn out from the portions to the short sides close to the portions and are formed via the arm parts 13 up to the connection parts 14b.

In FIG. 9, the electrode patterns 10a2 and 10b2 are formed to surround the gap parts 10c and 10d except for the central portions of the long sides of the mounting part 11. As described above, the strength of the arm parts 13 can be increased by forming the electrode patterns 10a2 and 10b2.

Furthermore, as illustrated in FIGS. 10, 11, and 13, the electrode patterns 10a2 and 10b2 are formed on the side surfaces of the arm parts 13 and the side surfaces of the connection parts 14b.

Moreover, as illustrated in FIGS. 12 and 14, in the back surface of the second pedestal 1b, the electrode patterns 10a2 and 10b2 are formed on the back sides of the arm parts 13 and the connection parts 14b.

Moreover, the conductive adhesive is formed near the four corners of the crystal piece 2 to fix the crystal piece 2.

Specifically, the crystal piece 2 is fixed with conductive adhesive to four rectangular patterns of the electrode patterns 10a2 and 10b2 formed on the mounting part 11, but an excitation electrode on the front side of the crystal piece 2 is connected to one of the electrode patterns 10a2 and 10b2 via conductive adhesive, an excitation electrode on the back side of the crystal piece 2 is connected to the other electrode pattern via conductive adhesive.

Assuming that the thickness of the mounting part 11 is “a” and the thickness of the arm parts 13 is “b”, the relationship is “a>b”. Moreover, the thickness “c” of the connection parts 14b has the relationship “c=a>b”.

In other words, the thickness “a” of the mounting part 11 and the thickness “c” of the connection parts 14b contacting the substrate of the package 3 are thick, and the thickness “b” of the arm parts 13 is thin.

As a result, even if vibration is added to the connection parts 14b from the outside, the vibration can be absorbed and relieved by the arm parts 13. For that reason, the influence of the vibration generated on the substrate does not affect the crystal piece 2 mounted on the mounting part 11.

Moreover, by making the thickness of the arm parts 13 thin, the arm parts 13 have flexibility with respect to stress and thus can easily absorb the influence of the vibration. Furthermore, by making the thickness of the mounting part 11 thicker than that of the arm parts 13 to increase the rigidity of the mounting part, it is possible to prevent the mounting part 11 itself from being deformed due to stress from the plurality of arm parts 13. As a result, the occurrence of stress between the mounting part 11 and the crystal piece 2 can be suppressed, and thus vibration resistance and impact resistance can be improved.

[Shape of Package: FIG. 15]

Next, a relationship between the second pedestal 1b and the package 3 will be explained with reference to FIG. 15. FIG. 15 is an explanatory view illustrating a cross section of the second pedestal and the package. Note that a configuration illustrated in FIG. 15 illustrates a package 3a.

As illustrated in FIG. 15, the package 3a has a configuration that a recessed portion has a step.

Specifically, at least portions to which the bottom surfaces of the connection parts 14b are connected protrude in a height direction to form step portions in the inner bottom surface of the recessed portion, and the connection parts 14b of the second pedestal 1b are connected to the step portions via solders 7a.

With the configuration of the package 3a, only the connection parts 14b of the second pedestal 1b are connected to the package 3a and thus the bottom surface of the mounting part 11 can be floated without contacting the bottom surface of the package 3a. Therefore, vibration from the connection parts 14b is absorbed by the arm parts 13 and is prevented from being transmitted to the mounting part 11.

In FIG. 15, the second pedestal 1b is simply illustrated with the same thickness, but the thickness of the arm parts 13 is thin actually.

[Shape of Another Package: FIG. 16]

Next, a relationship between the second pedestal 1b and another package 3 will be explained with reference to FIG. 16. FIG. 16 is an explanatory view illustrating a cross section of the second pedestal and the other package. Note that a configuration illustrated in FIG. 16 illustrates a package 3b.

As illustrated in FIG. 16, the package 3b has a configuration that a recessed portion does not have a step.

However, in the package 3b, protruding solders (bumps) 7b that can maintain the thickness of gold bumps etc. are formed on portions corresponding to the bottom surfaces of the connection parts 14b of the second pedestal 1b, and are connected to the connection parts 14b of the second pedestal 1b.

The bumps 7b may be made of any materials as long as they can form a thickness, and may be made of materials other than gold bumps.

As illustrated in FIG. 16, the bumps 7b such as gold bump for raising are formed on the bottom of the package 3b having the recessed portion and are connected to the connection parts 14b of the second pedestal 1b. Therefore, even if the mounting part 11 and the connection parts 14b have the same thickness, only the connection parts 14b are connected to the bottom surface of the recessed portion without making the mounting part 11 contact the bottom surface of the recessed portion of the package 3b, and thus the bottom surface of the mounting part 11 can be floated without contacting the bottom surface of the package 3b. As a result, vibration from the connection parts 14b is absorbed by the arm parts 13 and is prevented from being transmitted to the mounting part 11.

In FIG. 16, the second pedestal 1b is simply illustrated with the same thickness, but the thickness of the arm parts 13 is thin actually.

Moreover, the second pedestal 1b has the configuration that each surface of the mounting part 11, the arm parts 13, and the connection parts 14b is a plane (flush) and the mounting part 11 and the connection parts 14b protrude from the back surface.

[Effects of Second Pedestal]

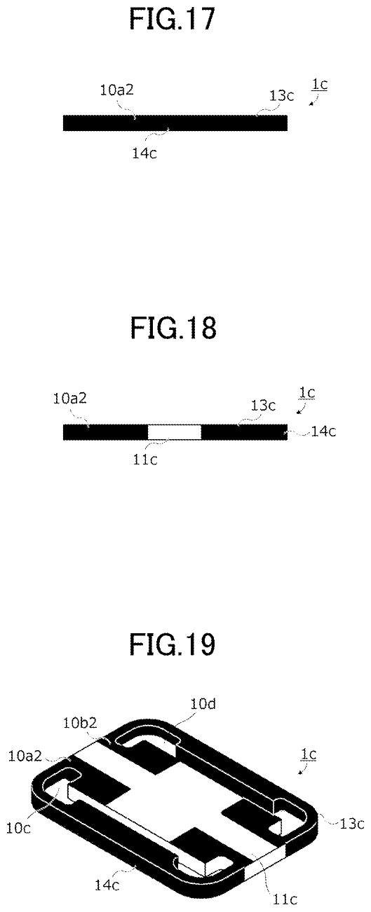

The second pedestal 1b has the configuration that the electrode patterns on the back sides of the connection parts 14b are fixed to the electrode patterns formed on the substrate of the package 3 by soldering and the mounting part 11 surrounded by the gap parts 10c and 10d is connected to the connection parts 14b by the arm parts 13. Moreover, the thicknesses of the connection parts 14b and the mounting part 11 are made the same and the thickness of the arm parts 13 is thinner than that of the connection parts 14b and the mounting part 11. Therefore, even if vibration from the outside is transmitted to the connection parts 14b, the vibration can be absorbed by the arm parts 13 to be prevented from being transmitted to the mounting part 11, and thus phase noise characteristics can be improved and a production cost can be reduced.

[Third Pedestal: FIGS. 17 to 19]

Next, a third pedestal 1c will be explained with reference to FIGS. 17 to 19. FIG. 17 is an explanatory view illustrating a long side surface of the third pedestal. FIG. 18 is an explanatory view illustrating a short side surface of the third pedestal. FIG. 19 is a perspective view illustrating a surface of the third pedestal.

As illustrated in FIGS. 17 to 19, the basic configuration of the third pedestal 1c is the same as that of the second pedestal 1b. The difference is that connection parts 14c, a mounting part 11c, and arm parts 13c have the same thickness.

According to the third pedestal 1c, by making the thicknesses of the mounting part 11c, the arm parts 13c, and the connection parts 14c the same, the arm parts 13c can be thickened and strengthened, and the third pedestal is not manufactured while changing the thickness depending on the component parts. Therefore, the third pedestal can be easily manufactured to reduce a production cost.

Moreover, similar to the second pedestal 1b, also in case of the third pedestal 1c, a vibrator is configured by mounting the vibration element of the crystal piece 2 on the pedestal by conductive adhesive and providing the pedestal in the package illustrated in FIGS. 15 and 16.

Furthermore, an oscillator is configured by providing an oscillation circuit etc. on the back recessed portion of the package.

The configuration of the third pedestal 1c is that the thickness of the arm parts 13c is thickened to have the same thickness as that of the mounting part 11 and the connection parts 14b of the second pedestal 1b and the overall thickness is uniform. However, the overall thickness may be uniformed by making the thickness of the mounting part 11c, the arm parts 13c, and the connection parts 14c of the third pedestal 1c thinner than that of the mounting part 11 and the connection parts 14b of the second pedestal 1b.

[Effects of Third Pedestal]

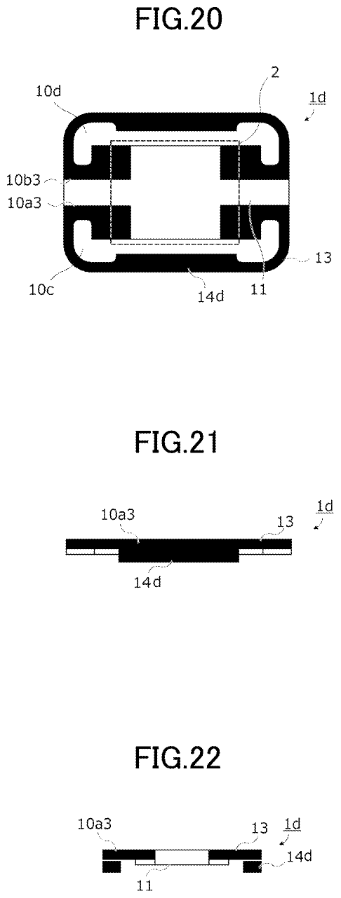

The third pedestal 1c has the configuration that the electrode patterns on the back sides of the connection parts 14c are fixed to the electrode patterns formed on the substrate of the package 3 by soldering and the mounting part 11c surrounded by the gap parts 10c and 10d is connected to the connection parts 14c by the arm parts 13c. Moreover, the thicknesses of the connection parts 14c, the mounting part 11c, and the arm parts 13c are also made the same. Therefore, even if vibration from the outside is transmitted to the connection parts, the vibration can be absorbed by the arm parts 13c to be prevented from being transmitted to the mounting part, and thus phase noise characteristics can be improved and a production cost can be further reduced.

[Fourth Pedestal: FIGS. 20 to 25]

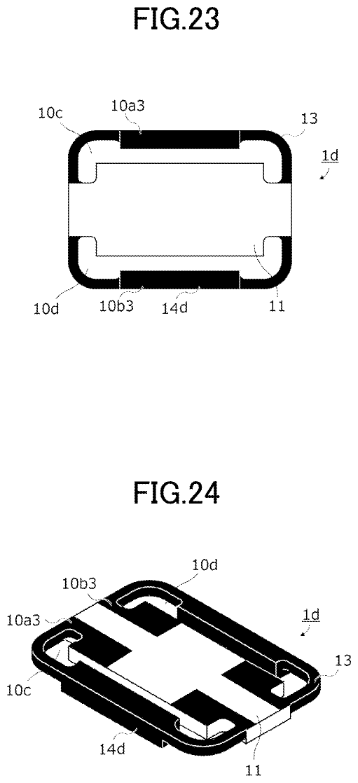

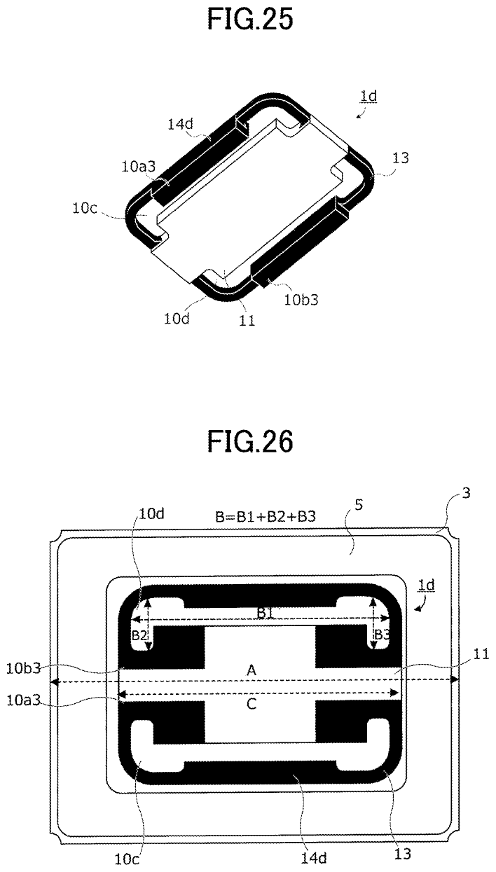

Next, a fourth pedestal 1d will be explained with reference to FIGS. 20 to 25. FIG. 20 is an explanatory view illustrating a surface of the fourth pedestal. FIG. 21 is an explanatory view illustrating a long side surface of the fourth pedestal. FIG. 22 is an explanatory view illustrating a short side surface of the fourth pedestal. FIG. 23 is an explanatory view illustrating a back surface of the fourth pedestal. FIG. 24 is a perspective view illustrating the surface of the fourth pedestal. FIG. 25 is a perspective view illustrating the back surface of the fourth pedestal.

As illustrated in FIG. 20, the fourth pedestal 1d includes the gap parts 10c and 10d that are formed inside along the two long sides of the main body, the central mounting part 11 that is sandwiched between the gap parts 10c and 10d and on which the crystal piece 2 is mounted, the arm parts 13 that are curved in an arc shape at the four corners of the main body, and connection parts 14d that are provided on the long sides of the mounting part 11 and are connected to electrodes formed on the substrate (bottom surface) of the package 3.

The arm parts 13 are curved to have an arm-like structure.

In other words, the fourth pedestal 1d has a configuration that the arm parts 13 and the connection parts 14d are formed to surround the substantially rectangular mounting part 11 and the mounting part 11 and the connection parts 14d are connected by the arm parts 13.

Moreover, the two U-shaped gap parts 10c and 10d are formed along the long sides of the mounting part 11. The gap parts 10c and 10d penetrate through the front and back of the fourth pedestal 1d.

Herein, the width of the short side (the vertical length of FIG. 20) of the mounting part 11 is narrower than that of the center. Thereby, the gap parts 10c and 10d are opened toward the up and down to have a U shape. With this configuration, the fourth pedestal has larger flexibility (elasticity).

Moreover, the connection parts 14d protrude toward the lower side (substrate side) of the package 3 compared to the other component parts. In other words, only the connection parts 14d contact the substrate of the package 3.

Moreover, as illustrated in FIGS. 20 and 23 to 25, the width of the connection parts 14d is wider than that of the arm parts 13 and thus a joining area with the substrate of the package 3 can be increased. On the other hand, the arm parts 13 are flexed to have flexibility by making the arm parts 13 a narrow width.

As illustrated in FIG. 20, electrode patterns 10a3 and 10b3 are formed on the surface of the fourth pedestal 1d. The electrode patterns 10a3 and 10b3 are formed of thin films of metal such as gold.

Specifically, square patterns to which conductive adhesive is applied are in portions overlapping with the crystal piece 2, and patterns are formed from the portions to the connection parts 14d via the arm parts 13 close to the portions.

In FIG. 20, the electrode patterns 10a3 and 10b3 are formed to surround the gap parts 10c and 10d except for the central portions on the long side and the short side of the mounting part 11. As described above, a metallic film is coated to increase the strength of the arm parts 13 by forming the electrode patterns 10a3 and 10b3.

Furthermore, as illustrated in FIGS. 21, 22, 24, and 25, the electrode patterns 10a3 and 10b3 are also formed on the side surfaces of the arm parts 13 and the connection parts 14d.

As illustrated in FIGS. 23 and 25, in the back surface of the fourth pedestal 1d, the electrode patterns 10a3 and 10b3 are also formed on the back sides of the arm parts 13 and the connection parts 14d.

The conductive adhesive is formed near the four corners of the crystal piece 2 to fix the crystal piece 2.

Specifically, the crystal piece 2 is fixed with conductive adhesive to four rectangular patterns of the electrode patterns 10a3 and 10b3 formed on the mounting part 11. Note that an excitation electrode on the front side of the crystal piece 2 is connected to one of the electrode patterns 10a3 and 10b3 via conductive adhesive and an excitation electrode on the back side of the crystal piece 2 is connected to the other electrode pattern via conductive adhesive.

Assuming that the thickness of the mounting part 11 is “a” and the thickness of the arm parts 13 “b”, the relationship is “a>b”. Moreover, the thickness “c” of the connection parts 14d has the relationship “c>a>b”.

In other words, the thickness “c” of the connection parts 14d contacting the substrate of the package 3 is the thickest, and the thickness “b” of the arm parts 13 is the thinnest.

This is a structure in which only the bottom surfaces of the connection parts 14d are connected to the substrate of the package 3 by most thickening the thickness of the connection parts 14d and thus the arm parts 13 and the mounting part 11 can be floated from the substrate.

As a result, even if vibration is added to the connection parts 14d from the outside, the vibration can be absorbed and relieved by the arm parts 13. For that reason, the influence of the vibration generated on the substrate does not affect the crystal piece 2 mounted on the mounting part 11.

Moreover, by most thinning the thickness of the arm parts 13, the arm parts 13 have flexibility with respect to stress and thus can easily absorb the influence of the vibration. Furthermore, by making the thickness of the mounting part 11 thicker than that of the arm parts 13 to increase the rigidity of the mounting part, it is possible to prevent the mounting part 11 itself from being deformed due to stress from the plurality of arm parts 13. As a result, the occurrence of stress between the mounting part 11 and the crystal piece 2 can be suppressed, and thus vibration resistance and impact resistance can be improved.

Note that portions where the arm parts 13 and the mounting part 11 are connected to each other and portions where the arm parts 13 and the connection parts 14 are connected to each other are weak against impact from the outside and are easy to be damaged. In the fourth pedestal 1d, because the electrode patterns 10a3 and 10b3 are formed to cover those connecting portions, damage is prevented in the connecting portions.

[Surfaces of Fourth Pedestal and Package: FIG. 26]

Next, the characteristic portions of the fourth pedestal 1d will be explained in detail with reference to FIG. 26. FIG. 26 is an enlarged view illustrating the surfaces of the fourth pedestal and the package. FIG. 26 illustrates a state where the fourth pedestal 1d is stored in the central recessed portion of the package 3 and the seam ring 5 is formed on the frame wall of the package 3. Herein, the side surface of the central recessed portion coincides with the inner circumference line of the seam ring 5. Alternatively, the side surface of the recessed portion may be located more inside.

As illustrated in FIG. 26, in the fourth pedestal 1d, each of the gap parts 10c and 10d includes a portion formed along the long side of the main body and portions formed along the short sides of the main body. The length of the portion formed along the long side is B1 and the lengths of the portions formed along the short sides are B2 and B3.

Moreover, the length of the long side of the package 3 is “A”.

Herein, the length B1 is a length not less than the half of the length A.

B1≥A/2

In the fourth pedestal 1d, the length B1 of the gap part 10d in the long-side direction is sufficiently long, but the length may be shorter than that in FIG. 26 if the length is equal to or greater than A/2.

Furthermore, in order to obtain sufficient effects of the fourth pedestal 1d, it is preferable that the gap parts 10c and 10d have the configuration that a sum B of the length B1 of the portion formed along the long side of the main body and the lengths B2 and B3 of the portions formed along the short sides is longer than a length C of the long side of the fourth pedestal 1d.

C<B(=B1+B2+B3)

Because the lengths of the long side and the short side of the arm parts 13 can be secured to sufficiently long values by employing such a configuration, vibration transmitted to the connection parts 14d can be absorbed by the arm parts 13 and phase noise characteristics can be improved.

[Effects of Fourth Pedestal]

The fourth pedestal 1d has the configuration that the electrode patterns on the back sides of the connection parts 14d are fixed to the electrode patterns formed on the substrate of the package 3 by soldering and the mounting part 11 surrounded by the gap parts 10c and 10d is connected to the connection parts 14d by the arm parts 13. Moreover, the length B1 of the gap parts 10c and 10d along the long side of the main body is not less than the half of the length A of the long side of the package 3. Therefore, even if vibration from the outside is transmitted to the connection parts 14d, the vibration can be absorbed by the arm parts 13 to be prevented from being transmitted to the mounting part 11 and thus phase noise characteristics can be improved.

### INDUSTRIAL APPLICABILITY

The present invention is suitable for a pedestal for a crystal piece, a crystal vibrator, and a crystal oscillator, which can improve vibration resistance by suppressing the influence of vibration from the outside and can improve phase noise characteristics.

What is claimed is:

1. A pedestal for a vibration element on which the vibration element is mounted and that is provided on a substrate of a package, the pedestal comprising:
two connection parts that are formed along a long side of a main body of the pedestal, the two connection parts contacting the substrate;
two gap parts that are formed along the long side inside the main body from the connection parts;
a mounting part that is sandwiched between the two gap parts, the vibration element being mounted on the mounting part; and
arm parts that are formed on four corners of the main body, the arm parts connecting the mounting part and the connection parts.

2. The pedestal according to claim 1, wherein the connection parts and the mounting part have a same thickness, and a thickness of each of the arm parts is thinner than that of the connection parts and the mounting part.

3. The pedestal according to claim 1, wherein the connection parts, the mounting part, and the arm parts have a same thickness.

4. The pedestal according to claim 1, wherein a length of each of the gap parts along the long side of the main body is equal to or greater than half of a length of a long side of the package.

5. The pedestal according to claim 4, wherein each of the gap parts includes a portion formed along the long side of the main body and portions formed along a short side of the main body, and a total length of the portion formed along the long side and the portions formed along the short side is longer than a length of the long side of the main body.

6. The pedestal according to claim 1, wherein the arm parts have a shape curved in an arc shape.

7. The pedestal according to claim 1, wherein the connection parts protrude toward the substrate.

8. The pedestal according to claim 1, wherein each of the arm parts has a thinner thickness than the mounting part and has a narrower width than each of the connection parts.

9. The pedestal according to claim 2, wherein
the mounting part includes a cutout portion in which a short side thereof is cut out toward a center side, and
the arm part extends to the short side of the cut-out mounting part and is connected to the mounting part.

10. The pedestal according to claim 3, wherein
the mounting part includes a cutout portion in which a short side thereof is cut out toward a center side, and
the arm part extends to the short side of the cut-out mounting part and is connected to the mounting part.

11. A vibrator including a pedestal on which a vibration element is mounted and that is provided on a substrate of a package,
wherein the pedestal comprises:
two connection parts that are formed along a long side of a main body of the pedestal, the two connection parts contacting the substrate;
two gap parts that are formed along the long side inside the main body from the connection parts;
a mounting part that is sandwiched between the two gap parts, the vibration element being mounted on the mounting part; and
arm parts that are formed on four corners of the main body, the arm parts connecting the mounting part and the connection parts.

12. The vibrator according to claim 11, wherein the pedestal is provided on the substrate on a bottom surface of a surface recessed portion of the package.

13. The vibrator according to claim 11, wherein the connection parts and the mounting part of the pedestal have a same thickness, and a thickness of each of the arm parts of the pedestal is thinner than that of the connection parts and the mounting part, and the connection parts of the pedestal are provided to contact a step portion formed inside a surface recessed portion of the package.

14. The vibrator according to claim 11, wherein the connection parts, the mounting part, and the arm parts of the pedestal have a same thickness, and the connection parts of the pedestal are provided to contact a step portion formed inside a surface recessed portion of the package.

15. The vibrator according to claim 11, wherein the connection parts and the mounting part of the pedestal have a same thickness, and a thickness of each of the arm parts of the pedestal is thinner than that of the connection parts and the mounting part, and the connection parts are provided to be raised by bumps so that a back surface of the mounting part of the pedestal does not contact the substrate on a bottom surface of a surface recessed portion of the package.

16. An oscillator including a pedestal on which a vibration element is mounted and that is provided on a substrate of a package, and an oscillation circuit being provided in the package,
wherein the pedestal comprises:
two connection parts that are formed along a long side of a main body of the pedestal, the two connection parts contacting the substrate;
two gap parts that are formed along the long side inside the main body from the connection parts;
a mounting part that is sandwiched between the two gap parts, the vibration element being mounted on the mounting part; and
arm parts that are formed on four corners of the main body, the arm parts connecting the mounting part and the connection parts.

17. The oscillator according to claim 16, wherein the pedestal is provided on the substrate on a bottom surface of a surface recessed portion of the package, and the oscillation circuit is mounted on a back recessed portion of the package.

18. The oscillator according to claim 16, wherein the connection parts and the mounting part of the pedestal have a same thickness, and a thickness of each of the arm parts of the pedestal is thinner than that of the connection parts and the mounting part, and the connection parts of the pedestal are provided to contact a step portion formed inside a surface recessed portion of the package, and the oscillation circuit is mounted on a back recessed portion of the package.

19. The oscillator according to claim 16, wherein the connection parts, the mounting part, and the arm parts of the pedestal have a same thickness, and the connection parts of the pedestal are provided to contact a step portion formed inside a surface recessed portion of the package, and the oscillation circuit is mounted on a back recessed portion of the package.

20. The oscillator according to claim 16, wherein the connection parts and the mounting part of the pedestal have a same thickness, and a thickness of each of the arm parts of the pedestal is thinner than that of the connection parts and the mounting part, and the connection parts are provided to be raised by bumps so that a back surface of the mounting part of the pedestal does not contact the substrate on a bottom surface of a surface recessed portion of the package, and the oscillation circuit is mounted on a back recessed portion of the package.
